(19) United States
(12) Patent Application Publication
(10) Pub. No.: US 2023/0290640 A1
(43) Pub. Date: Sep. 14, 2023

(54) MANUFACTURING METHOD OF SEMICONDUCTOR STRUCTURE AND SEMICONDUCTOR STRUCTURE

(71) Applicant: CHANGXIN MEMORY TECHNOLOGIES, INC., Hefei City (CN)

(72) Inventor: Hui WANG, Hefei City (CN)

(21) Appl. No.: 17/805,732

(22) Filed: Jun. 7, 2022

(30) Foreign Application Priority Data
Mar. 14, 2022 (CN) 202210246082.2

(51) Int. Cl. H01L 21/308; H01L 23/544; H01L 21/3065; H01L 21/311; H01L 21/768

(52) U.S. Cl. CPC H01L 21/3086; H01L 21/3065; H01L 21/31144; H01L 21/76898; H01L 23/544; H01L 2223/54426

(57) ABSTRACT

The present disclosure relates to the technical field of semiconductors, and provides a manufacturing method of a semiconductor structure and a semiconductor structure. The manufacturing method of a semiconductor structure includes: providing a base; forming, on a base, a barrier layer with a target thickness; performing first heat treatment on the barrier layer, a temperature of the first heat treatment being 85-100° C.; exposing the barrier layer, and performing second heat treatment on the barrier layer, a temperature of the second heat treatment being 85-100° C.; performing development on the barrier layer to form a through via region in the barrier layer; and etching the base according to the through via region to form a through via.

### CROSS-REFERENCE TO RELATED APPLICATION

This disclosure claims the priority of Chinese Patent Application No. 202210246082.2, submitted to the Chinese Intellectual Property Office on Mar. 14, 2022, the disclosure of which is incorporated herein in its entirety by reference.

### TECHNICAL FIELD

The present disclosure relates to the technical field of semiconductors, and in particular to a manufacturing method of a semiconductor structure and a semiconductor structure.

### BACKGROUND

In the related art, there are a great number of through-silicon vias (TSVs) during interconnection of semiconductor structures. Due to the large depth and long manufacturing time of the TSVs, a thick photoresist (PR) is used for shielding. Considering inherent attributes of the PR, while the PR becomes thicker, an internal stress in the PR is increased to cause cracks, thereby affecting the etching process.

### SUMMARY

According to a first aspect, the present disclosure provides a manufacturing method of a semiconductor structure, including:
providing a base;
forming, on a base, a barrier layer with a target thickness;
performing first heat treatment on the barrier layer, a temperature of the first heat treatment being 85-100° C.;
exposing the barrier layer, and performing second heat treatment on the barrier layer, a temperature of the second heat treatment being 85-100° C.;
performing development on the barrier layer to form a through via region in the barrier layer; and
etching the base according to the through via region to form a through via.

According to a second aspect, the present disclosure provides a semiconductor structure, which is formed by the above manufacturing method of a semiconductor structure.

### BRIEF DESCRIPTION OF THE DRAWINGS

The preferred implementations of the present disclosure will be described below in detail with reference to the accompanying drawings to make the objectives, features and advantages of the present disclosure more obvious. The accompanying drawings are merely exemplary illustrations of the present disclosure, and are not necessarily drawn to scale. The same reference numerals in the accompanying drawings always represent the same parts. In the drawings:

FIG. 1 is a schematic flowchart illustrating a manufacturing method of a semiconductor structure according to an exemplary implementation;

FIG. 2 is a schematic structural view of forming a base in a manufacturing method of a semiconductor structure according to an exemplary implementation;

FIG. 3 is a schematic structural view of forming a barrier layer in a manufacturing method of a semiconductor structure according to an exemplary implementation;

FIG. 4A is a schematic structural view of forming a through via region in a manufacturing method of a semiconductor structure according to an exemplary implementation;

FIG. 4B is a schematic structural view of forming an annular edge region and a through via region in a manufacturing method of a semiconductor structure according to an exemplary implementation;

FIG. 4C is a schematic structural view of forming an annular edge region in a manufacturing method of a semiconductor structure according to an exemplary implementation;

FIG. 5 is a schematic structural view of forming a through via in a manufacturing method of a semiconductor structure according to an exemplary implementation;

FIG. 6 is a schematic structural view of removing a barrier layer in a manufacturing method of a semiconductor structure according to an exemplary implementation;

FIG. 7 is a schematic structural view illustrating a barrier layer of a semiconductor structure according to an exemplary implementation;

FIG. 8 is a schematic structural view illustrating a barrier layer of a semiconductor structure according to another exemplary implementation; and

FIG. 9 is a schematic structural view illustrating a manufacturing state of a semiconductor structure according to an exemplary implementation.

### DETAILED DESCRIPTION

The typical embodiments embodying the features and advantages of the present disclosure are described in detail below. It should be understood that the present disclosure may have various changes in different embodiments, which do not depart from the scope of the present disclosure. The description and accompanying drawings herein are essentially used for the purpose of explanation, rather than limiting the present disclosure.

Different exemplary implementations of the present disclosure are described below with reference to the accompanying drawings. The accompanying drawings form a part of the present disclosure, which show by way of example different exemplary structures, systems, and steps that can implement various aspects of the present disclosure. It should be understood that other specific solutions of components, structures, exemplary apparatuses, systems, and steps may be used, and structural and functional modifications may be made without departing from the scope of the present disclosure. Moreover, although the terms such as “above”, “between”, and “within” may be used in this specification to describe different exemplary features and elements of the present disclosure, these terms are used herein only for convenience of description, for example, according to the directions of the examples in the accompanying drawings. Nothing in this specification should be understood as requiring a specific three-dimensional direction of the structure to fall within the scope of the present disclosure.

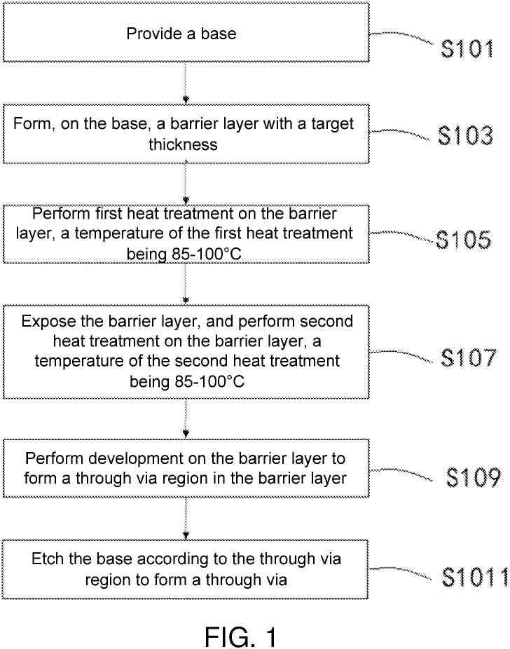

An embodiment of the present disclosure provides a manufacturing method of a semiconductor structure. Referring to FIG. 1, the manufacturing method of a semiconductor structure includes the following steps:

S101: Provide a base 10.

S103: Form, on the base 10, a barrier layer 20 with a target thickness.

S105: Perform first heat treatment on the barrier layer 20, a temperature of the first heat treatment being 85-100° C.

S107: Expose the barrier layer 20, and perform second heat treatment on the barrier layer, a temperature of the second heat treatment being 85-100° C.

S109: Perform development on the barrier layer 20 to form a through via region 21 in the barrier layer.

S1011: Etch the base 10 according to the through via region 21 to form a through via 30.

The barrier layer 20 with the target thickness is formed on the base 10. Before and after the barrier layer 20 is exposed, the first heat treatment and the second heat treatment are performed separately. The temperature of the first heat treatment is 85-100° C., and the temperature of the second heat treatment is 85-100° C. Therefore, the manufacturing method of a semiconductor structure provided by the embodiment of the present disclosure can lower a risk of cracks in the barrier layer 20, ensure that the base 10 is etched subsequently according to the through via region 21 formed in the barrier layer 20 after development, achieve the highly accurate through via 30, and improve the performance of the semiconductor structure.

It is to be noted that after the barrier layer 20 with the target thickness is formed on the base 10, the barrier layer 20 may be cured by controlling the temperature of the first heat treatment. The temperature of the first heat treatment is 85-100° C., namely the first heat treatment has a relatively low temperature. Consequently, the curing speed of the barrier layer 20 can be reduced to ease internal stress concentration of the barrier layer 20, thereby lowering the risk of cracks in the barrier layer 20. Therefore, the embodiment can lower the risk of cracks in the barrier layer 20 for a first time by controlling the temperature of the first heat treatment, and ensure that the barrier layer 20 serves as an effective barrier for the subsequent process.

After the barrier layer 20 is exposed, the second heat treatment is performed on the barrier layer 20. The temperature of the second heat treatment is 85-100° C., namely the second heat treatment has a relatively low temperature. Consequently, the curing speed of the barrier layer 20 can be reduced to ease the internal stress concentration of the barrier layer 20, thereby further lowering the risk of cracks in the barrier layer 20. It is also ensured that the barrier layer 20 has a reliable shielding capability and can take an effective protection effect during etching to achieve the highly accurate through via 30.

The embodiment can lower the risk of cracks in the barrier layer 20 for a second time by controlling the temperature of the second heat treatment. In combination with the temperature control on the first heat treatment, the embodiment can ensure the structural integrity of the barrier layer 20, and prevent the cracks caused by the stress concentration.

In an embodiment, the through via 30 may be a TSV.

In an embodiment, the barrier layer 20 may be a PR layer. Specifically, the barrier layer 20 is formed by coating the PR on the base 10. Post apply bake (PAB, namely the first heat treatment) is then performed on the barrier layer at 85-100° C., for fear of the massive stress concentration in the barrier layer 20.

The PR may be coated by spin coating. After the PAB, the barrier layer 20 is exposed, and post exposure bake (PEB, namely the second heat treatment) is performed on the barrier layer at 85-100° C., which can further prevent the massive stress concentration in the barrier layer 20.

In an embodiment, the target thickness is not greater than 8.9 µm. The relatively thin barrier layer 20 can prevent the risk of cracks in the subsequent process.

The target thickness of the barrier layer 20 is not greater than 8.9 µm, the PAB is performed at the temperature of 85-100° C. after the PR is coated on the base 10, and the PEB is performed at the temperature of 85-100° C. after the barrier layer 20 is exposed. Hence, in combination with the heat treatment performed twice at the relatively low temperature, the relatively thin barrier layer 20 can effectively reduce the internal stress concentration of the barrier layer 20, thereby lowering the risk of cracks in the barrier layer 20.

It is to be noted that as the target thickness of the barrier layer 20 is not greater than 8.9 µm, namely the barrier layer 20 is relatively thin, the internal stress of the barrier layer 20 is relatively small. By performing the heat treatment twice at the relatively low temperature, the embodiment can reduce the curing speed of the barrier layer 20 to ease the internal stress concentration of the barrier layer 20, thereby further lowering the risk of cracks in the barrier layer 20.

In an embodiment, the target thickness is in a range of 7-8 µm. It is ensured that the barrier layer 20 can effectively shield the base 10 and is relatively thin to reduce the internal stress of the barrier layer 20. In combination with the heat treatment performed twice at the relatively low temperature, the embodiment can reduce the curing speed of the barrier layer 20 to ease the internal stress concentration of the barrier layer 20, thereby further lowering the risk of cracks in the barrier layer 20.

In some embodiments, the target thickness of the barrier layer 20 may be 7 µm, 7.05 µm, 7.1 µm, 7.2 µm, 7.3 µm, 7.4 µm, 7.5 µm, 7.6 µm, 7.7 µm, 7.8 µm, 7.9 µm, 7.95 µm or 8 µm.

In an embodiment, the temperature of the first heat treatment is 88-95° C., namely the first heat treatment has a relatively low temperature. Consequently, the curing speed of the barrier layer 20 can be reduced to ease the internal stress concentration of the barrier layer 20, thereby lowering the risk of cracks in the barrier layer 20.

In some embodiments, the temperature of the first heat treatment may be 88° C., 88.5° C., 89° C., 90° C., 91° C., 92° C., 93° C., 94° C., 94.5° C. or 95° C.

In an embodiment, the temperature of the second heat treatment is 88-95° C., namely after the barrier layer 20 is exposed, the second heat treatment is performed on the barrier layer 20, and the second heat treatment has a relatively low temperature. Consequently, the curing speed of the barrier layer 20 can be reduced to ease the internal stress concentration of the barrier layer 20, thereby lowering the risk of cracks in the barrier layer 20.

In some embodiments, the temperature of the second heat treatment may be 88° C., 88.5° C., 89° C., 90° C., 91° C., 92° C., 93° C., 94° C., 94.5° C. or 95° C.

In an embodiment, the temperature of first heat treatment is the same as that of the second heat treatment. As both the temperature of first heat treatment and the temperature of the second heat treatment are low and consistent, the curing speed of the barrier layer 20 can be reduced to ease the internal stress concentration of the barrier layer 20, thereby lowering the risk of cracks in the barrier layer 20. The two heat treatment processes are simple, namely the adjustment on the temperature between the first heat treatment and the second heat treatment turns out to be unnecessary, so there are less manufacturing procedures of the semiconductor structure.

In an embodiment, plasma etching with a mixed gas as a supply gas is used to etch the base 10. The supply gas includes oxygen and a fluorocarbon compound. The oxygen has a flow of 30-40 sccm, and the fluorocarbon compound has a flow of 245-255 sccm, thereby repairing a shape of the through via region 21. Hence, the highly accurate through via 30 can be obtained according to the through via region 21 during etching.

It is to be noted that after the PR is coated on the base 10, the temperature of the PAB is controlled at 85-100° C. to reduce the curing speed of the PR and prevent the internal stress concentration of the barrier layer 20. However, while the curing speed of the barrier layer 20 is reduced, the shape of the barrier layer 20 is changed and cannot meet subsequent requirements. After the barrier layer 20 is exposed, the temperature of the PEB is controlled at 85-100° C. to reduce the curing speed of the barrier layer 20, such that the shape of the barrier layer 20 is further changed. In the embodiment, the plasma etching with the mixed gas as the supply gas is used to etch the base 10. The oxygen has the flow of 30-40 sccm, and the fluorocarbon compound has the flow of 245-255 sccm, namely the flow of the oxygen is reduced, while the flow of the fluorocarbon compound is increased, such that the shape of the barrier layer 20 is repaired during etching.

In some embodiments, the supply gas includes the oxygen and the fluorocarbon compound. The flow of the oxygen may be 30 sccm, 30.5 sccm, 31 sccm, 32 sccm, 33 sccm, 34 sccm, 35 sccm, 36 sccm, 37 sccm, 38 sccm, 39 sccm, 39.5 sccm or 40 sccm.

The flow of the fluorocarbon compound may be 245 sccm, 245.5 sccm, 246 sccm, 247 sccm, 248 sccm, 249 sccm, 250 sccm, 251 sccm, 252 sccm, 253 sccm, 254 sccm, 254.5 sccm or 255 sccm.

In an embodiment, while the development is performed on the barrier layer 20 to form the through via region 21 in the barrier layer, an annular edge region 13 of the base 10 is exposed, namely the edge region of the barrier layer 20 is removed. In this way, cracks formed by the edge region of the barrier layer 20 can be prevented from extending to the inside of the barrier layer 20, to reduce the risk of cracks in the barrier layer 20.

It is to be noted that when the barrier layer 20 with the target thickness of not greater than 8.9 µm is formed on the base 10 by the spin coating, the temperature of the PAB is controlled at 85-100° C. to expose the barrier layer 20, and the temperature of the PEB is controlled at 85-100° C., the internal stress concentration of the barrier layer 20 can be reduced, but the stress at the edge of the barrier layer 20 is highly concentrated to cause cracks first at the edge of the barrier layer 20. If not handled, the cracks will extend to the inside of the barrier layer 20 gradually in the subsequent process to cause the cracks of the barrier layer 20 in a wide range. In the embodiment, the development is performed on the barrier layer 20 to form the through via region 21 in the barrier layer, the annular edge region 13 of the base 10 is exposed simultaneously, namely the edge region of the barrier layer 20 is removed. In other words, the cracks at the edge of the barrier layer 20 are removed to prevent the extension of the cracks.

In an embodiment, the step of exposing the barrier layer 20 includes: Perform first exposure on the barrier layer 20, a region subjected to the first exposure corresponding to the edge region 13; and perform second exposure on the barrier layer 20, a region subjected to the second exposure corresponding to the through via region 21. The barrier layer 20 is exposed twice, with the first exposure for the edge region of the barrier layer 20, and the second exposure for the middle region of the barrier layer 20. Therefore, while the development is performed on the barrier layer 20 to form the through via region 21 in the barrier layer, the annular edge region 13 of the base 10 is exposed.

It is to be noted that there is a difference between the edge region of the barrier layer 20 and the middle region of the barrier layer 20, the edge region of the barrier layer 20 is thicker than the middle region of the barrier layer 20 and the thicker region is more likely to cause the cracks. In the embodiment, as the region subjected to the first exposure corresponds to the edge region 13, while the region subjected to the second exposure corresponds to the through via region 21, the through via region 21 and the annular edge region 13 can be formed synchronously. Meanwhile, the edge region of the barrier layer 20 is removed to further prevent the cracks.

In some embodiments, the step of exposing the barrier layer 20 includes: Perform exposure once on the barrier layer 20, a region subjected to the exposure corresponding to the edge region 13 and the through via region 21 at the same time.

In some embodiments, the step of exposing the barrier layer 20 includes: Perform first exposure on the barrier layer 20, a region subjected to the first exposure corresponding to the through via region 21; and perform second exposure on the barrier layer 20, a region subjected to the second exposure corresponding to the edge region 13.

In an embodiment, the edge region 13 has a width of 0.8-1.2 mm. It is ensured that the barrier layer 20 is not removed excessively and the cracks in the edge region of the barrier layer 20 can be effectively prevented, thereby lowering the risk of cracks in the barrier layer 20.

In some embodiments, the width of the edge region 13 may be 0.8 mm, 0.85 mm, 0.9 mm, 0.95 mm, 0.99 mm, 1 mm, 1.05 mm, 1.08 mm, 1.1 mm, 1.15 mm or 1.2 mm.

It is to be noted that the edge region 13 may be of an approximately annular shape, with the approximately same width at each place of the edge region 13. Nevertheless, the width at each place of the edge region 13 is in a range of 0.8-1.2 mm.

In an embodiment, when the base 10 is etched according to the through via region 21, the edge region 13 is shielded by a shield ring 40, so as not to damage the edge region 13 of the base 10 during etching.

While the development is performed on the barrier layer 20 to form the through via region 21 in the barrier layer, the annular edge region 13 of the base 10 is exposed, namely the edge region of the barrier layer 20 is removed. When the base 10 is etched subsequently, the barrier layer 20 exposes the edge region 13 of the base 10 and the region corresponding to the through via region 21 at the same time. The region corresponding to the through via region 21 is used to form the through via 30. If the edge region 13 is not shielded, the edge region 13 of the base 10 will be damaged during the etching. Therefore, the edge region 13 is shielded by the shield ring 40 in the embodiment to effectively protect the base 10 and prevent the damage to the edge region of the base 10.

In an embodiment, the shield ring 40 is wider than the edge region 13, which can ensure that the edge region 13 is effectively shielded, and prevent the damage to the edge region 13 of the base 10 when the plasma etching is used to etch the base 10.

In an embodiment, the shield ring 40 has a width of 1.3-1.6 mm. The shield ring 40 can effectively shield the edge region 13, and prevent the damage to the edge region 13 of the base 10 when the plasma etching is used to etch the base 10.

In some embodiments, the width of the shield ring 40 may be 1.3 mm, 1.31 mm, 1.32 mm, 1.35 mm, 1.4 mm, 1.45 mm, 1.46 mm, 1.47 mm, 1.48 mm, 1.49 mm, 1.5 mm, 1.51 mm, 1.52 mm, 1.55 mm, 1.56 mm, 1.57 mm, 1.58 mm, 1.59 mm or 1.6 mm.

In an embodiment, the shield ring 40 may be as wide as the edge region 13, namely the shield ring 40 and the edge region 13 may overlap completely, which not only achieves the compact structure, but also can ensure that the edge region 13 is shielded, and prevent the damage to the edge region 13 of the base 10 when the plasma etching is used to etch the base 10.

In an embodiment, there is a gap between the shield ring 40 and the barrier layer 20, such that the barrier layer 20 is not affected by the shield ring 40. For example, with the gap between the shield ring 40 and the barrier layer 20, the shield ring 40 neither pollutes the barrier layer 20 nor contacts the barrier layer 20 to damage the barrier layer 20.

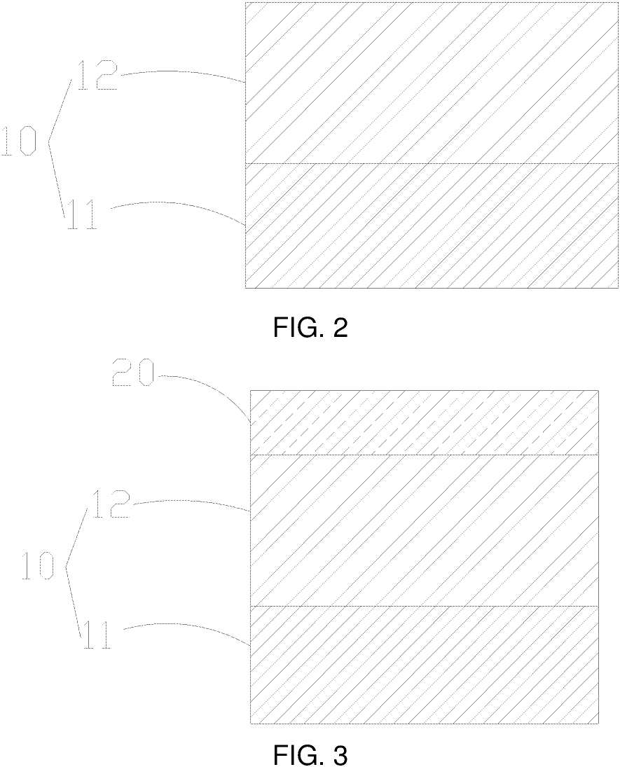

In an embodiment, as shown in FIG. 2 to FIG. 6, the manufacturing method of a semiconductor structure includes the following steps:

As shown in FIG. 2, a base 10 is provided. The base 10 may include a substrate 11 and a dielectric layer 12. The dielectric layer 12 is located on the substrate 11.

The substrate 11 may include a part made of a silicon-containing material. The substrate 11 may be made of any suitable material, including, for example, at least one of silicon, monocrystalline silicon, polycrystalline silicon, amorphous silicon, silicon-germanium, monocrystalline silicon-germanium, polycrystalline silicon-germanium and carbon-doped silicon.

The dielectric layer 12 may be a spin-on dielectric (SOD). Electronic devices may be provided in the SOD. The electronic devices are not limited, and may be selected according to actual needs. The electronic devices may include P-channel metal oxide semiconductor (PMOS), N-channel metal oxide semiconductor (NMOS), etc.

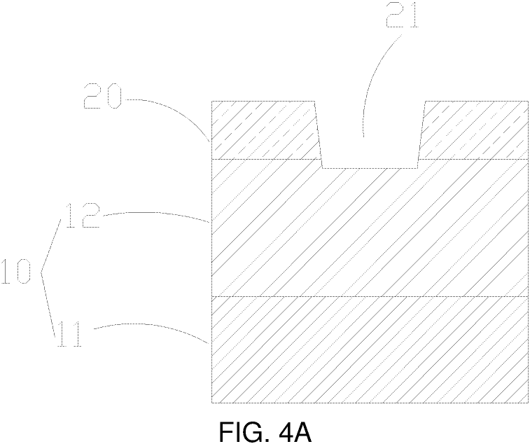

As shown in FIG. 3, a barrier layer 20 is formed on the dielectric layer 12 by spin coating. The barrier layer 20 covers an upper surface of the dielectric layer 12. First heat treatment may be performed on the barrier layer 20, a temperature of the first heat treatment being 85-100° C. The barrier layer 20 is exposed, and second heat treatment is performed on the barrier layer, a temperature of the second heat treatment being 85-100° C.

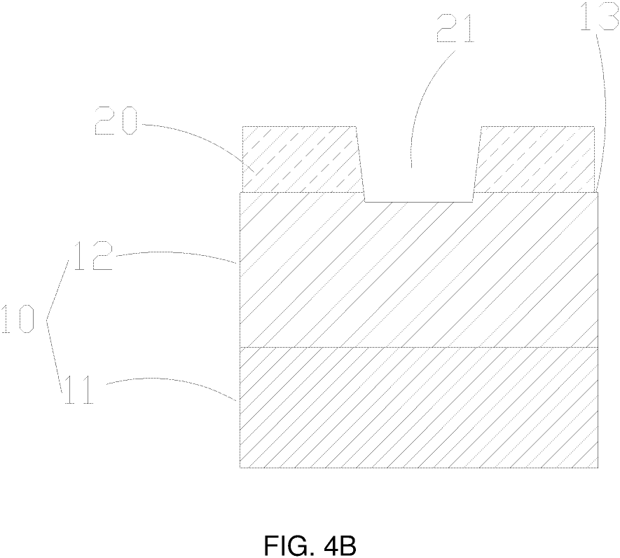

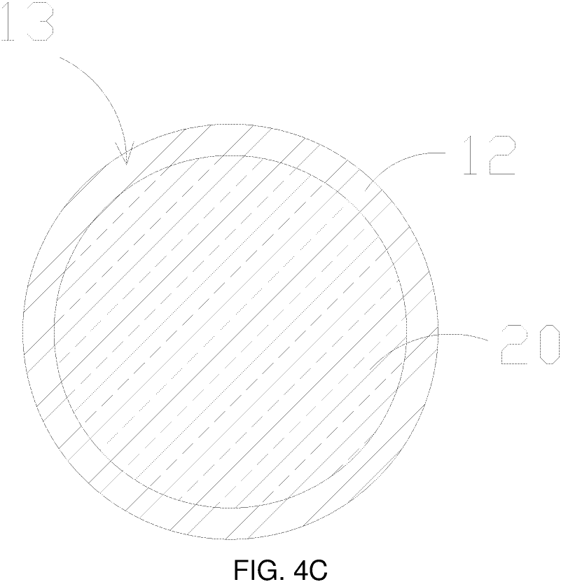

As shown in FIG. 4A, development is performed on the barrier layer 20 to form a through via region 21 in the barrier layer 20. The barrier layer 20 is exposed once and developed to form the through via region 21 in the barrier layer 20.

As shown in FIG. 4B and FIG. 4C, while the development is performed on the barrier layer 20 to form the through via region 21 in the barrier layer 20, an annular edge region 13 of the base 10 is exposed. First exposure and second exposure are performed on the barrier layer 20, a region subjected to the first exposure corresponding to the edge region 13, and a region subjected to the second exposure corresponding to the through via region 21. Therefore, while the through via region 21 is formed in the barrier layer 20 upon development, the annular edge region 13 of the base 10 is exposed.

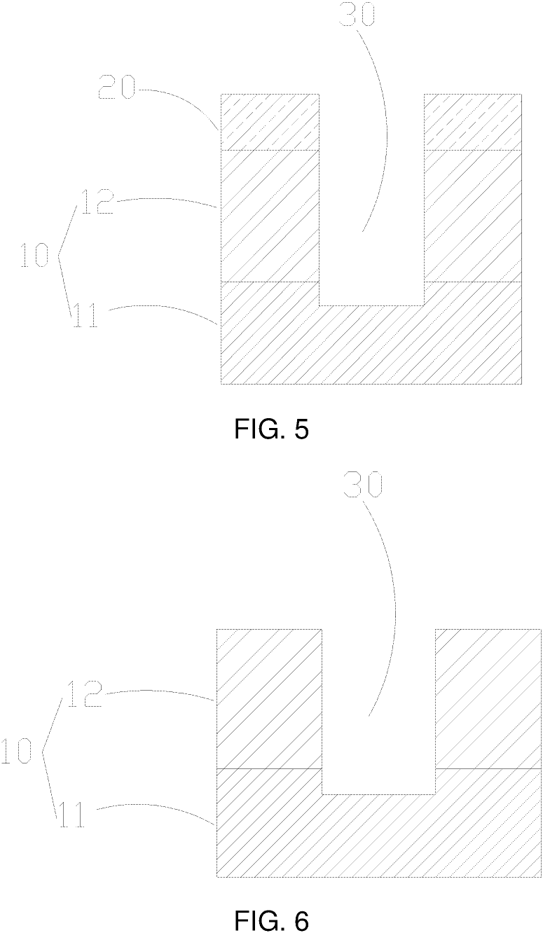

As shown in FIG. 5, plasma etching with a mixed gas as a supply gas is used to etch the base 10, thereby forming a through via 30 in the base 10. The through via 30 may penetrate through the dielectric layer 12, and a part of the through via 30 is located in the substrate 11.

As shown in FIG. 4A, FIG. 4B and FIG. 5, after the first heat treatment and the second heat treatment, the shape of the through via region 21 is changed. Nevertheless, the plasma etching with the mixed gas as the supply gas for etching the base 10 can repair the shape of the through via region 21.

As shown in FIG. 6, the barrier layer 20 is removed to form the through via 30 in the base 10.

In an embodiment, after the development, the base 10 is etched according to the through via region 21 to prevent third heat treatment on the barrier layer 20, which not only can reduce the manufacturing process of the semiconductor structure, but also can prevent the internal stress of the barrier layer 20 caused by the heat treatment and can prevent the cracks in the barrier layer 20.

It is to be noted that after the PR is coated on the base 10, the temperature of the PAB is controlled at 85-100° C. to reduce the curing speed of the PR and prevent the internal stress concentration of the barrier layer 20. After the barrier layer 20 is exposed, the temperature of the PEB is controlled at 85-100° C. to reduce the curing speed of the barrier layer 20. After the development, post develop bake (PDB) is forbidden, so as not to affect the shape of the barrier layer 20 and not to generate the internal stress in the barrier layer 20 for long-time baking on the barrier layer 20, thereby preventing the cracks of the barrier layer 20 and ensuring the structure of the barrier layer 20.

In an embodiment, an alignment mark 22 is formed on the barrier layer 20 through a photomask. The alignment mark 22 is provided with an arcuate circumferential edge. The arcuate edge is unlikely to form stress concentration and thus can prevent stress concentration of the alignment mark 22. Therefore, when the barrier layer 20 is cured, an outward pulling force for the alignment mark 22 is not concentrated at some position to prevent the cracks of the barrier layer 20.

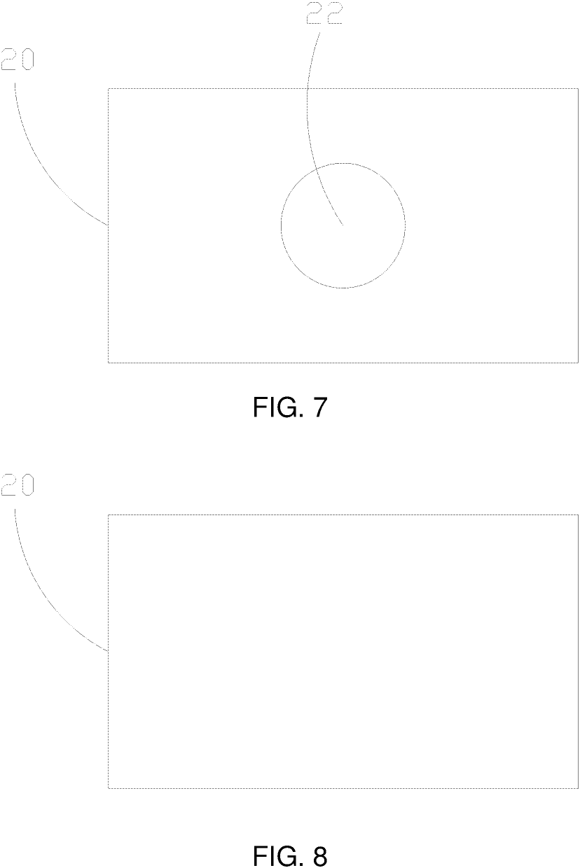

In an embodiment, as shown in FIG. 7, the alignment mark 22 is provided with a circular circumferential edge, namely the alignment mark 22 is under a consistent force in each direction to lower the risk of cracks in the barrier layer 20.

In an embodiment, the alignment mark 22 may also be provided with an elliptical circumferential edge.

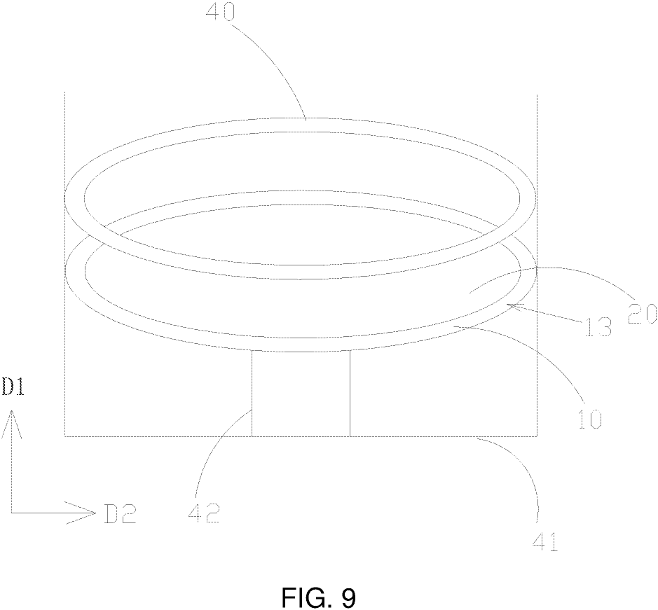

In an embodiment, as shown in FIG. 8, the alignment mark 22 may not be formed on the barrier layer 20, namely the alignment mark 22 may not be formed on the barrier layer 20 in case of a small alignment offset, so as to prevent the cracks of the barrier layer 20 caused by the alignment mark 22.

In an embodiment, as shown in FIG. 9, the base 10 is provided in a chamber 41. A support portion 42 may be provided in the chamber 41. The base 10 is provided on the support portion 42, and the shield ring 40 may be fixed in the chamber 41. There is a gap between the shield ring 40 and the barrier layer 20 in the first direction D1, and the shield ring 40 directly faces the edge region 13. As the width of the shield ring 40 in the second direction D2 is greater than that of the edge region 13 in the second direction D2, the edge region 13 can be effectively shielded, and when the plasma etching is used to etch the base 10, the edge region 13 of the base 10 is not damaged.

In some embodiments, the support portion 42 may be fixed in the chamber 41. The support portion 42 is detachably provided in the chamber 41. The support portion 42 is located approximately at a middle position of the chamber 41. The shield ring 40 may be connected to the chamber 41 through other components, or, the shield ring 40 may be directly clamped on the chamber 41, or, the shield ring 40 may be directly adhered on the chamber 41. Accordingly, the support portion 42 may be provided in the chamber 41 through other components, or, the support portion 42 may be directly clamped on the chamber 41. There are no limits made on the connection manner between the support portion 42 and the chamber 41 as well as the connection manner between the shield ring 40 and the chamber 41.

An embodiment of the present disclosure further provides a semiconductor structure, which is formed by the above manufacturing method of a semiconductor structure.

The semiconductor structure in the embodiment of the present disclosure is formed by the manufacturing method of a semiconductor structure. The barrier layer 20 with the target thickness is formed on the base 10. Before and after the exposure is performed on the barrier layer 20, the first heat treatment and the second heat treatment are performed separately. The temperature of the first heat treatment is 85-100° C., and the temperature of the second heat treatment is 85-100° C. Therefore, the semiconductor structure can lower a risk of cracks in the barrier layer 20, ensure that the base 10 is etched subsequently according to the through via region 21 formed in the barrier layer 20 after development, achieve the highly accurate through via 30, and improve the performance of the semiconductor structure.

A through via 30 is formed in the base 10. The base 10 may include a substrate 11 and a dielectric layer 12. The dielectric layer 12 is located on the substrate 11.

The substrate 11 may include a part made of a silicon-containing material. The substrate 11 may be made of any suitable material, including, for example, at least one of silicon, monocrystalline silicon, polycrystalline silicon, amorphous silicon, silicon-germanium, monocrystalline silicon-germanium, polycrystalline silicon-germanium and carbon-doped silicon.

The dielectric layer 12 may be a SOD. Electronic devices may be provided in the SOD. There are no limits made on the type of the electronic devices.

The through via 30 may be a TSV. The TSV interconnection can reduce the thickness of the chip under the same length. With logic modules arranged horizontally and piled vertically, it significantly reduces the resistor-capacitor (RC) delay and the inductance effect, improves the transmission speed and the microwave transmission for the digital signal, and achieves the connection in a higher density and a higher aspect ratio.

Those skilled in the art may easily figure out other implementations of the present disclosure after considering the specification and practicing the invention disclosed herein. The present disclosure is intended to cover any variations, purposes, or applicable changes of the present disclosure. Such variations, purposes or applicable changes follow the general principle of the present disclosure and include common knowledge or conventional technical means in the technical field which is not disclosed in the present disclosure. The specification and implementations are merely considered as illustrative, and the real scope and spirit of the present disclosure are directed by the appended claims.

It should be noted that, the present disclosure is not limited to the precise structures described above and shown in the drawings, and can be modified and changed in many ways without departing from the scope of the present disclosure. The scope of the present disclosure is defined by the appended claims.

1. A manufacturing method of a semiconductor structure, comprising:
providing a base;
forming, on a base, a barrier layer with a target thickness;
performing first heat treatment on the barrier layer, a temperature of the first heat treatment being 85-100° C.;
exposing the barrier layer, and performing second heat treatment on the barrier layer, a temperature of the second heat treatment being 85-100° C.;
performing development on the barrier layer to form a through via region in the barrier layer; and
etching the base according to the through via region to form a through via.

2. The manufacturing method of a semiconductor structure according to claim 1, wherein the target thickness is in a range of 7-8 µm.

3. The manufacturing method of a semiconductor structure according to claim 1, wherein the temperature of the first heat treatment is the same as that of the second heat treatment.

4. The manufacturing method of a semiconductor structure according to claim 1, wherein plasma etching with a mixed gas as a supply gas is used to etch the base, wherein
the supply gas comprises oxygen and a fluorocarbon compound; and the oxygen has a flow of 30-40 sccm, and the fluorocarbon compound has a flow of 245-255 sccm, so as to repair a shape of the through via region.

5. The manufacturing method of a semiconductor structure according to claim 1, wherein the performing development on the barrier layer to form a through via region in the barrier layer, an annular edge region of the base is exposed simultaneously.

6. The manufacturing method of a semiconductor structure according to claim 5, wherein the edge region has a width of 0.8-1.2 mm.

7. The manufacturing method of a semiconductor structure according to claim 5, wherein when the base is etched according to the through via region, the edge region is shielded by a shield ring.

8. The manufacturing method of a semiconductor structure according to claim 7, wherein the shield ring is wider than the edge region.

9. The manufacturing method of a semiconductor structure according to claim 8, wherein the shield ring has a width of 1.3-1.6 mm.

10. The manufacturing method of a semiconductor structure according to claim 7, wherein there is a gap between the shield ring and the barrier layer.

11. The manufacturing method of a semiconductor structure according to claim 5, wherein the exposing the barrier layer comprises:
performing first exposure on the barrier layer, a region subjected to the first exposure corresponding to the edge region; and
performing second exposure on the barrier layer, a region subjected to the second exposure corresponding to the through via region.

12. The manufacturing method of a semiconductor structure according to claim 1, wherein after the development, the base is etched according to the through via region to prevent third heat treatment on the barrier layer.

13. The manufacturing method of a semiconductor structure according to claim 1, wherein an alignment mark is formed on the barrier layer through a photomask, the alignment mark being provided with an arcuate circumferential edge.

14. The manufacturing method of a semiconductor structure according to claim 13, wherein the alignment mark is provided with a circular circumferential edge.

15. A semiconductor structure, formed by the manufacturing method of a semiconductor structure according to claim 1.

16. The manufacturing method of a semiconductor structure according to claim 2, wherein the temperature of the first heat treatment is the same as that of the second heat treatment.

17. The manufacturing method of a semiconductor structure according to claim 2, wherein plasma etching with a mixed gas as a supply gas is used to etch the base, wherein
the supply gas comprises oxygen and a fluorocarbon compound; and the oxygen has a flow of 30-40 sccm, and the fluorocarbon compound has a flow of 245-255 sccm, so as to repair a shape of the through via region.

18. The manufacturing method of a semiconductor structure according to claim 6, wherein when the base is etched according to the through via region, the edge region is shielded by a shield ring.

19. The manufacturing method of a semiconductor structure according to claim 2, wherein after the development, the base is etched according to the through via region to prevent third heat treatment on the barrier layer.

20. The manufacturing method of a semiconductor structure according to claim 2, wherein an alignment mark is formed on the barrier layer through a photomask, the alignment mark being provided with an arcuate circumferential edge.
